(19) United States
(12) Patent Application Publication
(10) Pub. No.: US 2017/0204510 A1
(43) Pub. Date: Jul. 20, 2017

(54) SUBSTRATE PROCESSING DEVICE

(71) Applicant: ULVAC, INC., Chigasaki-shi, Kanagawa (JP)

(72) Inventors: Tetsushi FUJINAGA, Chigasaki-shi (JP); Atsuhito IHORI, Chigasaki-shi (JP); Masahiro MATSUMOTO, Chigasaki-shi (JP); Noriaki TANI, Chigasaki-shi (JP); Harunori IWAI, Chigasaki-shi (JP)

(21) Appl. No.: 15/326,032

(22) PCT Filed: Jul. 23, 2015
(86) PCT No.: PCT/JP2015/070905

§ 371 Date: Jan. 12, 2017

(30) Foreign Application Priority Data
Jul. 31, 2014 (JP) 2014-156605

(51) Int. Cl. C23C 14/34; H01J 37/32; H05K 3/16; H01J 37/34

(52) U.S. Cl. CPC C23C 14/3464; H01J 37/3417; H01J 37/32752; H05K 3/16

(57) ABSTRACT

A substrate processing apparatus includes a sputter chamber, two targets located in the sputter chamber to form thin films on two film formation surfaces of a substrate through sputtering, and a transport mechanism that transports the substrate along a transport passage located in the sputter chamber. One of the two targets is located at one side of the transport passage opposed to one of the two film formation surfaces of the substrate at a front side with respect to a direction in which the substrate is transported. Another one of the two targets is located at another side of the transport passage opposed to another one of the two film formation surfaces of the substrate at a rear side with respect to the direction in which the substrate is transported.

### RELATED APPLICATIONS

The present application is a National Phase entry of PCT Application No. PCT/JP2015/070905, filed Jul. 23, 2015, which claims priority from Japanese Patent Application No. 2014-156605, filed Jul. 31, 2014, the disclosures of which are hereby incorporated by reference herein in their entirety.

### TECHNICAL FIELD

The present invention relates to a substrate processing apparatus that processes two surfaces of a substrate.

### BACKGROUND ART

The use of, for example, film-like substrates as mount substrates on which electronic components are mounted has gradually increased over these years to reduce the weight and the thickness of electronic devices.

A thin substrate such as a film-like substrate has lower thermal resistance than a glass substrate, which is widely used in the prior art. When film formation is performed on such a thin substrate through, for example, sputtering, sputtered particles having high energy reach a surface of the substrate. This increases the temperature of the substrate surface. When the temperature of the substrate surface exceeds the tolerance temperature of the material forming the substrate, deformation or the like may occur in the substrate. Thus, when film formation is performed on a thin substrate, the film formation needs to be performed in a temperature range that does not exceed the tolerance temperature of the material forming the substrate.

Double-surface film formation, in which film formation is performed on two surfaces of a substrate, may be performed to increase the density of the circuit patterns. In this case, when films are simultaneously formed on the two surfaces of the substrate, the temperature of the substrate tends to increase more easily than when single-surface film formation is performed. Thus, film formation is performed on the substrate twice, one surface at a time.

One example of a device that performs film formation on a substrate one surface at a time uses a transport robot to change the direction of the substrate. For example, when film formation is completed on one film formation surface of a substrate, the transport robot rotates the substrate and transports the substrate into a film formation device that performs film formation on the other film formation surface of the substrate. Patent document 1 describes an example of a substrate processing apparatus that includes a transport robot.

Patent Document 1: Japanese Laid-Open Patent Publication No. 2013-58565

### SUMMARY OF THE INVENTION

When a substrate processing apparatus includes a rotation mechanism, such as a transport robot, to rotate a substrate, the rotation mechanism rotates the substrate and transports the substrate to substrate processing chambers. Consequently, the operation time of the rotation mechanism is a bottleneck that limits the production amount. Thus, there is a demand for a substrate processing apparatus that forms thin films on the two surfaces of a substrate one surface at a time with higher production efficiency. The same demand also applies to a device in which a thin substrate is the subject of substrate processing and a substrate processing apparatus that needs to cool a substrate.

It is an object of the present invention to provide a substrate processing apparatus that increases the production efficiency when performing double-surface film formation.

One aspect of the present invention is a substrate processing apparatus. The substrate processing apparatus includes a sputter chamber, two targets located in the sputter chamber to form thin films on two film formation surfaces of a substrate through sputtering, and a transport mechanism that transports the substrate along a transport passage located in the sputter chamber. One of the two targets is located at one side of the transport passage opposed to one of the two film formation surfaces of the substrate at a front side with respect to a direction in which the substrate is transported. Another one of the two targets is located at another side of the transport passage opposed to another one of the two film formation surfaces of the substrate at a rear side with respect to the direction in which the substrate is transported.

In the above configuration, in the sputter chamber, one of the targets located at the front side with respect to the substrate transport direction forms a thin film on one film formation surface of the substrate that is opposed to the target. Additionally, the other target located at the rear side with respect to the substrate transport direction forms a thin film on the other film formation surface of the substrate that is opposed to the target. Thus, film formation is performed on one surface at a time without rotating the substrate. This increases the production efficiency in double-surface film formation.

Preferably, in the above substrate processing apparatus, the sputter chamber is one of a first sputter chamber and a second sputter chamber that are arranged next to each other to be at the front side and the rear side with respect to the transport direction, and the two targets located in the first sputter chamber and the two targets located in the second sputter chamber are located at different positions in the transport direction alternately at one side and the other side of the transport passage.

In the above configuration, the four targets, which include the two targets of the first sputter chamber located at the front side and the two targets of the second sputter chamber located at the rear side, are alternately located at one side and the other side of the transport passage. Thus, even when film formation is performed twice on each of two surfaces of the film substrate, the film formation is performed on one surface at a time without rotating the substrate. This increases the production efficiency in double-surface film formation.

Preferably, the above substrate processing apparatus further includes a reverse sputter chamber that cleans the two film formation surfaces of the substrate when the substrate is transported to the reverse sputter chamber prior to transportation to the sputter chamber. The substrate processing apparatus also includes two bias electrodes located in the reverse sputter chamber. Bias voltage is applied to the two bias electrodes. The two bias electrodes are separately located at the front side and the rear side with respect to the transport direction and at one side and the other side of the transport passage.

In the above configuration, in the reverse sputter chamber, the bias electrode located at the front side of the transport passage attracts positive ions to a film formation surface located at a side opposite to the bias electrode. Thus, reverse sputtering is performed on the film formation surface. Additionally, the bias electrode located at the rear side of the transport passage performs reverse sputtering on a film formation surface located at a side opposite to the bias electrode. Thus, reverse sputtering is performed on one surface at a time without rotating the substrate. This increases the production efficiency in double-surface film formation.

Preferably, the above substrate processing apparatus further includes a backward structural body including the sputter chamber. The substrate processing apparatus also includes a substrate attachment portion that is located at an unloading port side of the backward structural body and attaches the substrate to a substrate holder. Further, the substrate processing apparatus includes a forward structural body that transports the substrate, which is attached to the substrate holder, from an unloading port side of the backward structural body to a loading port side of the backward structural body. The forward structural body includes a heating portion that heats the substrate at a preset upper limit temperature or below.

In the above configuration, while transporting the substrate, which is attached to the substrate holder, from the unloading side to the loading side of the backward structural body, the substrate is heated by the heating portion located in the forward structural body. The heating portion heats the substrate at the preset upper limit temperature or below. Thus, the substrate is degassed while preventing deformation or the like of the substrate depending on the setting of the upper limit temperature.

Preferably, in the substrate processing apparatus, the transport mechanism includes a controller that controls transportation of the substrate to the forward structural body and transportation of the substrate to the backward structural body from the forward structural body. In accordance with unloading of the substrate from the backward structural body, the controller loads a substrate, on which a film has not yet been formed, onto the backward structural body from the forward structural body.

In the above configuration, in accordance with unloading of the substrate from the backward structural body, another substrate is loaded onto the backward structural body. Thus, the substrates that have been preheated in the forward structural body are sequentially transported at timings that allow for the process in the backward structural body 22. This increases the production efficiency in double-surface film formation.

### BRIEF DESCRIPTION OF THE DRAWINGS

FIG. 1 is a schematic side view illustrating the structure of one embodiment of a substrate processing apparatus.

FIG. 2 is a perspective view of a substrate holder to which a film substrate is attached in the substrate processing apparatus illustrated in FIG. 1.

FIG. 3 is a cross-sectional view illustrating a portion of the substrate holder illustrated in FIG. 2.

FIG. 4 is a schematic view illustrating a transport mechanism of the substrate processing apparatus illustrated in FIG. 1.

FIG. 5 is a schematic plan view illustrating the structure of the substrate processing apparatus illustrated in FIG. 1.

FIG. 6 is a schematic view illustrating the structure of a reverse sputtering device of the substrate processing apparatus illustrated in FIG. 1.

FIG. 7 is a schematic cross-sectional view of an electrostatic chuck located in the reverse sputtering device illustrated in FIG. 6.

FIG. 8 is a schematic view illustrating the structure of a sputtering device of the substrate processing apparatus illustrated in FIG. 1.

FIG. 9 is a schematic cross-sectional view of electrostatic chucks located in the sputtering device illustrated in FIG. 8.

FIG. 10 is a front view illustrating a modified example of a substrate holder.

### DESCRIPTION OF THE EMBODIMENTS

One embodiment of a substrate processing apparatus according to the present invention will now be described. In the present embodiment, the substrate processing apparatus performs sputtering on two surfaces of a substrate on which an electronic component is mounted to form an adhesion layer, which serves as the base of wires, and a seed layer, which is used when plating is performed to form the wires. The substrate, which is a subject of film formation, is a film of a substrate (hereafter, referred to as film substrate).

The main component of the film substrate is a resin. The material of the film substrate is, for example, an acrylic resin, a polyamide resin, a melamine resin, a polyimide resin, a polyester resin, cellulose, or a copolymer resin of them. Alternatively, the material of the film substrate is an organic natural compound such as gelatin or casein.

More specifically, the material forming the film substrate is polyester, polyethylene terephthalate, polybutylene terephthalate, polymethylene methacrylate, acryl, polycarbonate, polystyrene, triacetate, polyvinyl alcohol, polyvinyl chloride, polyvinylidene chloride, polyethylene, ethylene-vinylacetate copolymer, polyvinyl butyral, a metal ion bridging ethylene-methacrylate copolymer, polyurethane, cellophane, or the like. Preferably, polyethylene terephthalate, polycarbonate, polymethylene methacrylate, or triacetate is used as the material forming the film substrate.

Preferably, the thickness of the film substrate is 1 mm or less to increase the effect of the present embodiment. More preferably, the thickness of the film substrate is 100 μm or less. The length of one side (width or height in plan view) of the film substrate is, for example, 500 mm to 600 mm.

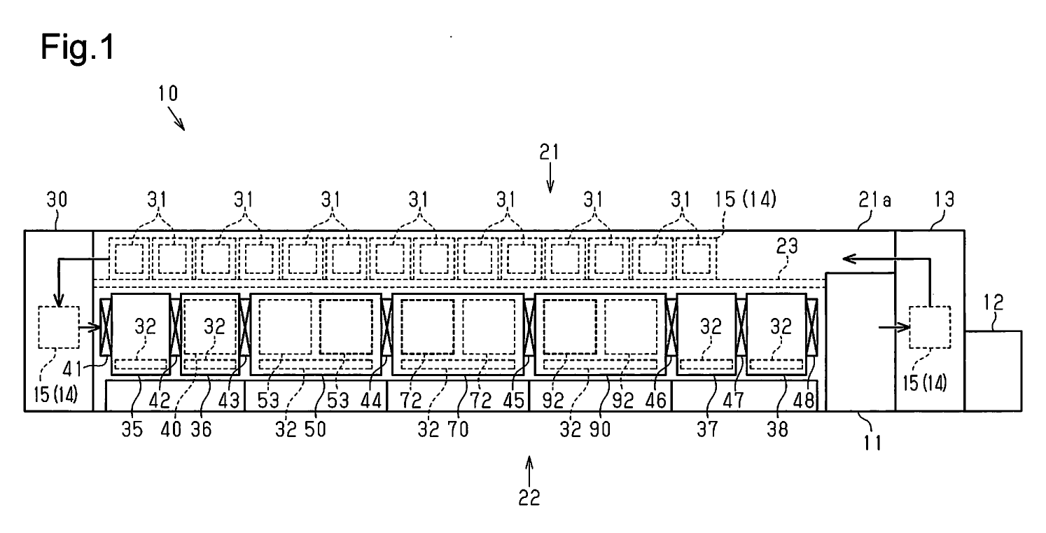

The structure of a substrate processing apparatus 10 will now be schematically described with reference to FIGS. 1 to 5.

The substrate processing apparatus 10 includes a substrate attachment portion 11 and a first substrate lift 13. The substrate attachment portion 11 attaches a film substrate 15 to a substrate holder 14 prior to film formation and detaches the film substrate 15 from the substrate holder 14 subsequent to the film formation. The substrate attachment portion 11 and the first substrate lift 13 are controlled by a controller 12.

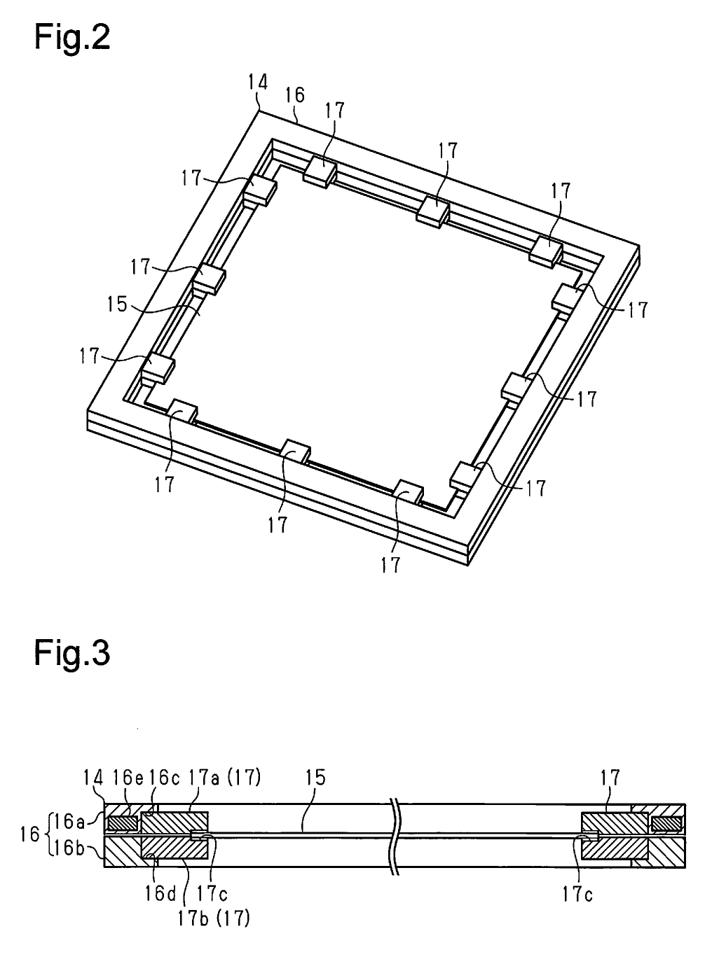

As illustrated in FIG. 2, the substrate holder 14 includes a frame 16 and substrate fasteners 17, which are arranged on inner surfaces of the frame 16. The substrate fasteners 17 are formed by magnets and arranged on the four sides of the frame 16.

As illustrated in FIG. 3, the frame 16 includes a first frame 16a and a second frame 16b. Groove-shaped engaged portions 16c, 16d are formed at inner sides of the first frame 16a and the second frame 16b, respectively. The first frame 16a and the second frame 16b are fastened to each other by a fastener (not illustrated) or the like. Magnets 16e are embedded in the first frame 16a at positions where the substrate fasteners 17 are located or throughout the region of the first frame 16a. Each substrate fastener 17 includes two fastening pieces 17a, 17b. The substrate fastener 17 has one end that includes a groove 17c. The groove 17c receives an edge of the film substrate 15. The groove 17c may be omitted depending on the thickness of the film substrate 15.

When attaching the film substrate 15 to the substrate holder 14, for example, the fastening pieces 17b of the substrate fasteners 17 are arranged in the engaged portion 16d of the second frame 16b and the film substrate 15 is located at a predetermined position relative to the second frame 16b. The fastening pieces 17a are also arranged in the engaged portion 16c of the first frame 16a. The fastening pieces 17a are attracted toward the first frame 16a by magnetic force of the magnets 16e. The first frame 16a, on which the fastening pieces 17a are arranged, is placed on the second frame 16b where the film substrate 15 is located on the fastening pieces 17b. Consequently, the film substrate 15 is fastened to the frame 16 by the substrate fasteners 17.

As illustrated in FIG. 1, the film substrate 15, which is attached to the substrate holder 14 at the substrate attachment portion 11, is lifted by the first substrate lift 13 and transported into a forward structural body, which is located above the substrate attachment portion 11 in the vertical direction.

The forward structural body 21 includes an elongated housing 21a and a forward transport passage 23, which is located in the housing 21a. The forward transport passage 23 transports the film substrate 15, which is attached to the substrate holder 14, from the first substrate lift 13 toward a second substrate lift 30, which is located at a side opposite to the first substrate lift 13.

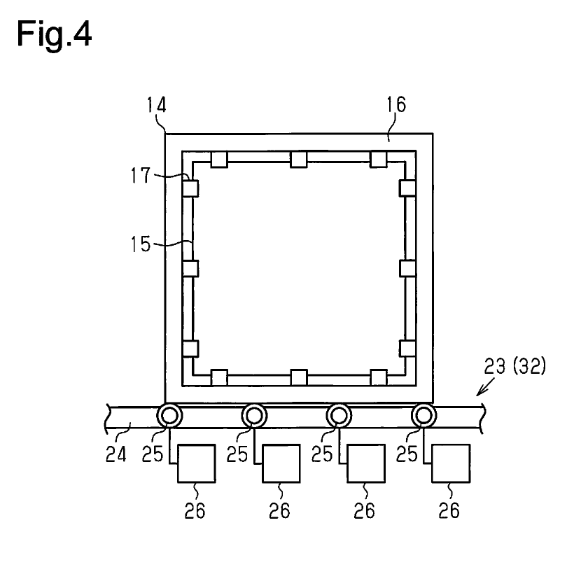

As illustrated in FIG. 4, the forward transport passage 23 includes a transport rail 24 and transport rollers 25. The transport rollers 25 are rotatable relative to the transport rail 24. Each transport roller 25 is driven by a drive source, for example, a transport motor 26. The transport motors 26 are controlled by the controller 12. The transport rail 24, the transport rollers 25, the transport motors 26, and the controller 12 form a transport mechanism that transports the film substrate 15.

As illustrated in FIG. 1, the housing 21a includes a longitudinal portion that includes heaters 31. The heaters 31 are located at opposite sides of the forward transport passage 23 and heat the film substrate 15 from opposite sides when transported along the forward transport passage 23. The heaters 31 are arranged in the longitudinal direction of the housing 21a. The film substrate 15 is hygroscopic due to the properties of the material forming the film substrate 15. Thus, the film substrate 15 is degassed when continuously heated by the heaters 31.

Each heater 31 is formed by, for example, a sheathed heater in which a metal pipe accommodates a heating wire with an insulator located in between. The temperature of the heater 31 is controlled by the controller 12 at an upper limit temperature Tmax or below to prevent deformation of the film substrate 15. The upper limit temperature Tmax is set in accordance with the material of the film substrate 15.

The number of the heaters 31 is adjusted so that the heating time in the forward structural body 21 is set to be longer than or equal to time needed to degas the film substrate 15 or substantially equal to the necessary time.

The controller 12 controls the second substrate lift 30 to sequentially lower the film substrates 15 that have been degassed and transport the film substrates 15 to a backward structural body 22, which is located below the forward structural body 21 in the vertical direction.

The backward structural body 22 includes a reverse sputtering device 50, a first sputtering device 70, and a second sputtering device 90. The reverse sputtering device 50 performs reverse sputtering, which cleans two surfaces of the film substrate 15. The first sputtering device 70 forms an adhesion layer on the film substrate 15. The second sputtering device 90 forms a seed layer on the film substrate 15.

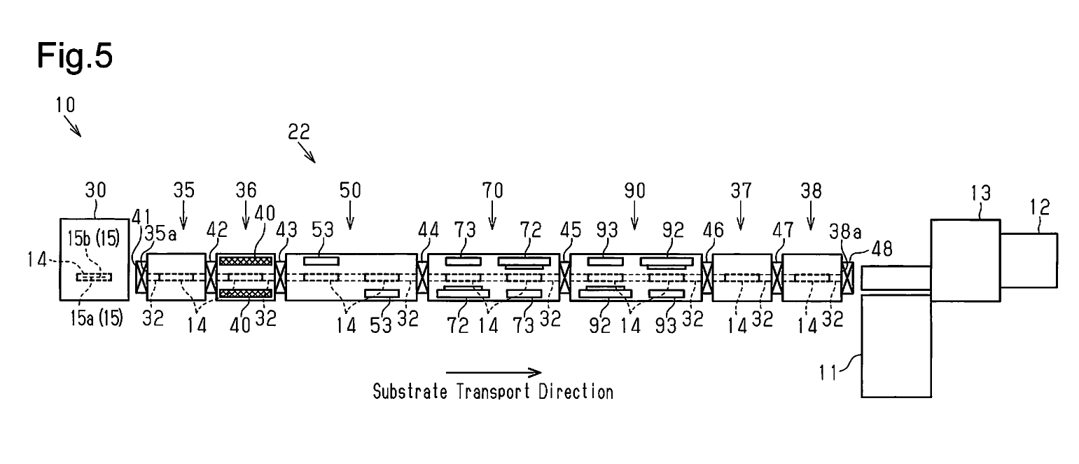

A loading chamber 35, which includes a loading port 35a (refer to FIG. 5), and a first preliminary chamber 36 are located between the second substrate lift 30 and the reverse sputtering device 50. A second preliminary chamber 37 and an unloading chamber 38, which includes an unloading port 38a (refer to FIG. 5), are located between the second sputtering device 90 and the substrate attachment portion 11.

Each of the loading chamber 35, the first preliminary chamber 36, the reverse sputtering device 50, the first sputtering device 70, the second sputtering device 90, the second preliminary chamber 37, and the unloading chamber 38 includes a backward transport passage 32. In the same manner as the forward transport passage 23, the backward transport passage 32 includes a transport rail 24 and transport rollers 25. The transport rollers 25 are connected to transport motors 26. The transport motors 26 of the backward transport passage 32 are also controlled by the controller 12. The film substrate 15 is linearly transported along the backward transport passage 32 from the second substrate lift 30 toward the substrate attachment portion 11 in the backward structural body 22.

Gate valves 41 to 43 are respectively located at the loading port 35a of the loading chamber 35, between the loading chamber 35 and the first preliminary chamber 36, and at the exit of the first preliminary chamber 36. The loading chamber 35 and the first preliminary chamber 36 are adjusted in a predetermined pressure range by a vent (not illustrated). Also, gate valves 46 to 48 are respectively located between the second sputtering device 90 and the second preliminary chamber 37, between the second preliminary chamber 37 and the unloading chamber 38, and at the exit of the unloading chamber 38. The second preliminary chamber 37 and the unloading chamber 38 are adjusted in a predetermined pressure range by a vent (not illustrated).

The first preliminary chamber 36 accommodates heaters 40 at opposite sides of the backward transport passage 32 (refer to FIG. 5). Each heater 40 is formed, for example, by a sheathed heater. The temperature of the heater 40 is controlled at the foregoing upper limit temperature or below by the controller 12. In the first preliminary chamber 36, the final degassing process is performed by heating the two surfaces of the film substrate 15 prior to film formation.

The heaters 40 in the first preliminary chamber 36 and the heaters 31 in the forward structural body 21 may be set to the same heating temperature or different heating temperatures. When the heaters 40 in the first preliminary chamber 36 are set to a higher heating temperature than the heaters 31 in the forward structural body 21, the temperature of the film substrate 15 continues to increase until immediately prior to the film formation. This limits gas adsorption caused by decreases in the temperature of the film substrate 15.

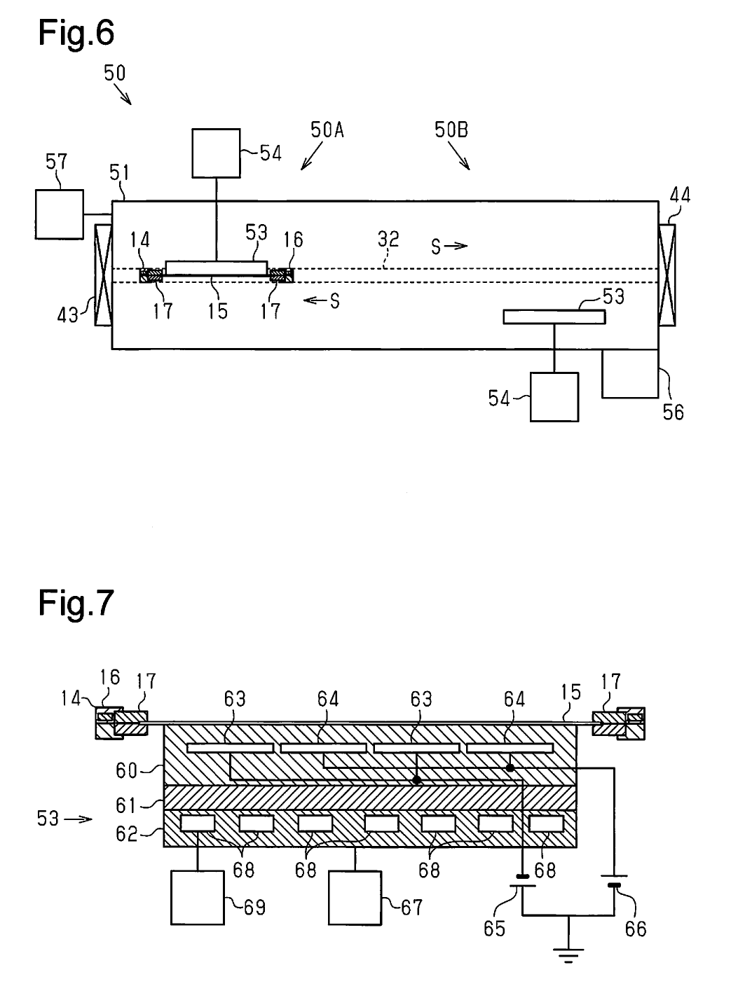

As illustrated in FIG. 5, the reverse sputtering device 50 includes two electrostatic chucks 53. Each electrostatic chuck 53 includes a bias electrode to which high frequency power is supplied. The reverse sputtering device 50 generates plasma including electrons and positive ions of a sputter gas in a reverse sputter chamber 51 (refer to FIG. 6) and applies a bias voltage to the electrostatic chucks 53. This attracts the positive ions from the plasma to the surface of the film substrate 15 and removes collected matter from the film substrate 15.

One of the electrostatic chucks 53 is located at a front side with respect to a substrate transport direction, which is the direction in which the film substrate 15 is transported. The other electrostatic chuck 53 is located at a rear side with respect to the substrate transport direction. The front electrostatic chuck 53 is located at the left side and the rear electrostatic chuck 53 is located at the right side as viewed from the entrance side of the reverse sputtering device 50.

The first sputtering device 70 includes two sets of first cathode units 72, each of which includes a target, and electrostatic chucks 73. The main component of the targets is, for example, titanium. One of the two sets of the first cathode units 72 and the electrostatic chucks 73 is located at the front side with respect to the substrate transport direction. The other set of the first cathode unit 72 and the electrostatic chuck 73 is located at the rear side with respect to the substrate transport direction. The two sets of the first cathode units 72 and the electrostatic chucks 73 are located at positions that do not overlap with each other in the substrate transport direction. The front first cathode unit 72 and the rear first cathode unit 72 are located at different sides of the backward transport passage 32. That is, the two first cathode units 72 are located at different positions in the transport direction of the film substrate 15 and also different positions in a direction orthogonal to the transport direction.

The second sputtering device 90 includes gate valves 45, 46. The gate valves 45, 46 are respectively located between the second sputtering device 90 and the first sputtering device 70 and between the second sputtering device 90 and the second preliminary chamber 37. Also, the second sputtering device 90 includes two sets of second cathode units 92, each of which includes a target, and electrostatic chucks 93. The main component of the targets is, for example, copper.

One of the two sets of the second cathode units 92 and the electrostatic chucks 93 is located at the front side with respect to the substrate transportation direction. The other set of the second cathode unit 92 and the electrostatic chuck 93 is located at the rear side with respect to the substrate transportation direction. The two sets of the second cathode units 92 and the electrostatic chucks 93 are located at positions that do not overlap with each other in the substrate transport direction. The front second cathode unit 92 and the rear second cathode unit 92 are located at different sides of the backward transport passage 32. That is, the two second cathode units 92 are located at different positions in the transport direction of the film substrate 15 and also different positions in the direction orthogonal to the transport direction.

Thus, the two first cathode units 72 of the first sputtering device 70 and the two second cathode units 92 of the second sputtering device 90 are alternately arranged at one side and at the other side with respect to the transport direction of the film substrate 15. Also, in the reverse sputtering device 50, the electrostatic chucks 53 are alternately arranged from side to side in the transport direction.

The controller 12 controls the transport motors 26 to pass the film substrate 15, which is vertically held on the transport rail 24, through the reverse sputtering device 50, the first sputtering device 70, and the second sputtering device 90. In the reverse sputtering device 50, the film substrate 15 is reverse-sputtered in the order of one film formation surface defining a right surface 15a and the other film formation surface defining a left surface 15b as viewed from the entrance of the reverse sputtering device 50.

In the first sputtering device 70, thin films are formed in the order of the right surface 15a and the left surface 15b. Subsequently, in the second sputtering device 90, thin films are formed in the order of the right surface 15a and the left surface 15b. In this manner, the substrate is alternately processed in the order of the right surface 15a and the left surface 15b when the film substrate 15 is transported through the reverse sputtering device 50, the first sputtering device 70, and the second sputtering device 90. Thus, after one film formation surface is processed, the film formation surface is located at a side opposite to the other film formation surface and cooled while the other film formation surface is processed.

### [Structure of Reverse Sputtering Device]

The structure and the operation of the reverse sputtering device will now be described with reference to FIGS. 6 and 7.

As illustrated in FIG. 6, the backward transport passage 32 linearly extends in the reverse sputter chamber 51 between the gate valve 43, which is located at the entrance side, and a gate valve 44, which is located at the exit side.

The reverse sputter chamber 51 is connected to a vent 56, which discharges the gas from an inner void of the reverse sputter chamber 51, and a sputter gas supply portion 57, which supplies a sputter gas containing argon into the inner void. The sputter gas may contain nitrogen gas, oxygen gas, or hydrogen gas other than argon. Alternatively, the sputter gas may be a mixture of at least two of the four gasses, which include argon. The vent 56 and the sputter gas supply portion 57 are controlled by the controller 12.

The reverse sputtering device 50 includes a front reverse sputtering portion 50A and a rear reverse sputtering portion 50B. The front reverse sputtering portion 50A and the rear reverse sputtering portion 50B have the same structure. Thus, the structure of the front reverse sputtering portion 50A will only be described.

The reverse sputtering portion 50A includes one electrostatic chuck 53. The front electrostatic chuck 53 is located at the left side of the backward transport passage 32 as viewed from the entrance side. The rear electrostatic chuck 53 is located at the right side of the backward transport passage 32 as viewed from the entrance.

The electrostatic chuck 53 attracts the film substrate 15 with force generated between the film substrate 15 and the electrostatic chuck 53. The electrostatic chuck 53 also absorbs heat from the film substrate 15, the temperature of which has increased due to reverse sputtering, to cool the film substrate 15. The electrostatic chuck 53 is coupled to an electrostatic chuck shifter 54, which shifts the electrostatic chuck 53 between a contact position where the electrostatic chuck 53 is in contact with the film substrate 15 located in the backward transport passage 32 and a non-contact position where the electrostatic chuck 53 is not in contact with the film substrate 15 located in the backward transport passage 32.

As illustrated in FIG. 7, the electrostatic chuck 53 includes a stacked body in which an insulation plate 60, a copper plate 61, and a bias electrode 62 are stacked. The insulation plate 60, which is located in the uppermost layer and has the form of a rectangular plate, includes a base formed by a ceramic formed, for example, from aluminum oxide, a resin such as a polyimide resin, or the like.

Positive electrodes 63 and negative electrodes 64 are embedded in the insulation plate 60. The positive electrodes 63 and the negative electrodes 64 are elongated and alternately spaced apart from one another. The positive electrodes 63 are electrically connected to a positive electrode power supply 65. The negative electrodes 64 are electrically connected to a negative electrode power supply 66. The positive electrode power supply 65 applies a relatively positive voltage to the positive electrodes 63. The negative electrode power supply 66 applies a relatively negative voltage to the negative electrodes 64. The application of the voltages to the positive electrodes 63 and the negative electrodes 64 attracts the film substrate 15 to the insulation plate 60.

The bias electrode 62 is connected to a bias high frequency power supply 67. The bias high frequency power supply 67 supplies high frequency power to the bias electrode 62. Preferably, the high frequency power has a frequency of, for example, 1 MHz or higher and 6 MHz or lower. Alternatively, the bias high frequency power supply 67 may be configured to supply high frequency power of a relatively high frequency and high frequency power of a relatively low frequency. In this case, preferably, high frequency power of 13 MHz or higher and 28 MHz or lower and high frequency power of 100 kHz or higher and 1 MHz or lower are supplied.

The bias electrode 62 includes a cooling medium passage 68, through which a cooling medium passes. The cooling medium passage 68 has the form of, for example, a curvature that curves in the plate-shaped bias electrode 62 multiple times. The cooling medium passage 68 is connected to a cooling medium circulator 69. The cooling medium circulator 69 circulates the cooling medium in the cooling medium passage 68. The cooling medium is a cooling liquid such as cooling water, a fluorine solution, or an ethylene glycol solution or a cooling gas such as helium gas or argon gas.

When the film substrate 15, which is attached to the substrate holder 14, is transported into the reverse sputter chamber 51 from the gate valve 43, the transport motors 26 are driven to locate the film substrate 15 at a predetermined position. The electrostatic chuck shifter 54 is also driven to shift the electrostatic chuck 53 to the contact position. The positive electrode power supply 65 and the negative electrode power supply 66 supply power to the positive electrodes 63 and the negative electrodes 64 to attract the film substrate 15 to the insulation plate 60.

The vent 56 is driven, and the sputter gas is supplied into a plasma generation void S. This adjusts the reverse sputter chamber 51 to the predetermined pressure. When the bias high frequency power supply 67 supplies high frequency power to the bias electrode 62 with the reverse sputter chamber 51 adjusted to the predetermined pressure, plasma that includes positive ions of the sputter gas and electrons is formed in the plasma generation void S. The positive ions in the plasma are attracted to the surface of the film substrate 15 having a negative potential. This removes collected matter or the like from the film formation surface located at a side opposite to the surface that is in contact with the electrostatic chuck 53. Thus, the film formation surface is cleaned.

The front reverse sputtering portion 50A continuously performs reverse sputtering on one film formation surface (right surface 15a) of the film substrate 15 for a predetermined time. Subsequently, the electrostatic chuck shifter 54 is driven to shift the electrostatic chuck 53 to the non-contact position from the contact position.

The transport motors 26 are driven to locate the film substrate 15 at a predetermined position in the rear reverse sputtering portion 50B. In the same manner as the front reverse sputtering portion 50A, the rear reverse sputtering portion 50B performs reverse sputtering on the other film formation surface (left surface 15b). During this time, the film formation surface (right surface 15a), on which reverse sputtering has been performed by the front reverse sputtering portion 50A, is in contact with and cooled by the electrostatic chuck 53.

### [Structure of Sputtering Device]

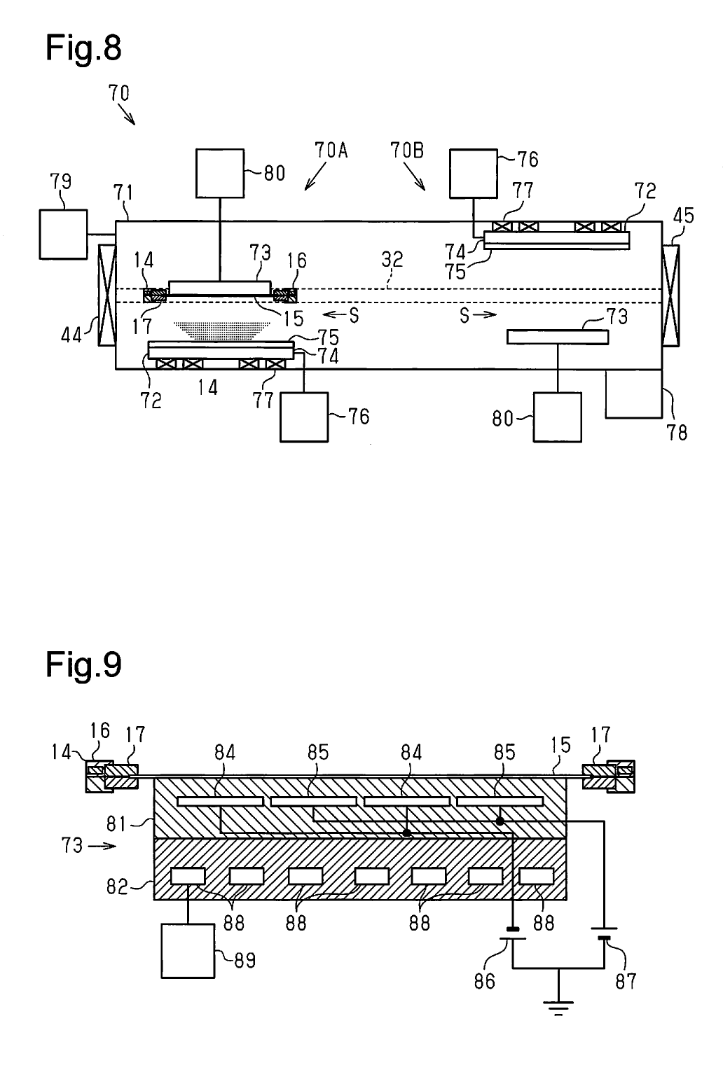

The structure and the operation of the first sputtering device 70 and the second sputtering device 90 will now be described with reference to FIGS. 8 and 9. The first sputtering device 70 and the second sputtering device 90 differ from each other in the material of the targets but otherwise have the same structure. Thus, the structure of the first sputtering device 70 will only be described. The structure of the second sputtering device 90 will not be described in detail.

The first sputtering device 70 includes the backward transport passage 32 that linearly extends from the gate valve 44, which is located at the entrance side, toward the gate valve 45, which is located at the exit side. The backward transport passage 32 is collinear with the backward transport passage 32 of the reverse sputtering device 50 and the backward transport passage 32 of the second sputtering device 90.

A sputter chamber 71 is connected to a vent 78, which discharges the gas from an inner void of the sputter chamber 71, and a sputter gas supply portion 79, which supplies a sputter gas into the inner void. The sputter gas may be the same as that used in the reverse sputtering device 50.

The first sputtering device 70 includes a front sputtering portion 70A and a rear sputtering portion 70B. The front sputtering portion 70A and the rear sputtering portion 70B are located at different sides of the backward transport passage 32. The front sputtering portion 70A and the rear sputtering portion 70B have the same structure. Thus, the structure of the front sputtering portion 70A will only be described.

The front sputtering portion 70A includes one set of the first cathode unit 72 and the electrostatic chuck 73. The first cathode unit 72 is opposed to the electrostatic chuck 73 spaced apart by a plasma generation void S.

The first cathode unit 72 includes a backing plate 74 and a target 75 that contains titanium as the main component. The target 75 is located on a surface of the backing plate 74 that is located toward the electrostatic chuck 73. The second sputtering device 90 includes a target 75 that contains copper as the main component.

The backing plate 74 is electrically connected to a target power supply 76. The backing plate 74 includes a rear surface on which magnet circuits 77 are formed. The magnet circuits 77 form a magnetic field in the plasma generation void S.

The electrostatic chuck 73 attracts the film substrate 15 with force generated between the film substrate 15 and the electrostatic chuck 73. The electrostatic chuck 73 also absorbs heat from the film substrate 15, the temperature of which has increased due to sputtering, to cool the film substrate 15. The electrostatic chuck 73 is coupled to an electrostatic chuck shifter 80, which shifts the electrostatic chuck 73 between a contact position where the electrostatic chuck 73 is in contact with the film substrate 15 located in the backward transport passage 32 and a non-contact position where the electrostatic chuck 73 is not in contact with the film substrate 15 located in the backward transport passage 32.

As illustrated in FIG. 9, the electrostatic chuck 73 of the first sputtering device 70 has substantially the same structure as the electrostatic chuck 53 of the reverse sputtering device 50 but differs from the electrostatic chuck 53 of the reverse sputtering device 50 in that the electrostatic chuck 73 does not include the bias electrode 62.

That is, the electrostatic chuck 73 of the first sputtering device 70 includes an insulation plate 81, in which positive electrodes 84 and negative electrodes 85 are embedded, and a cooling plate 82, in which a cooling medium passage 88 is formed. The positive electrodes 84 are electrically connected to a positive electrode power supply 86. The negative electrodes 85 are electrically connected to a negative electrode power supply 87. The cooling medium passage 88 is connected to a cooling medium circulator 89.

When the film substrate 15, which is attached to the substrate holder 14, is transported into the sputter chamber 71 from the gate valve 44, the transport motors 26 are driven to locate the film substrate 15 at an opposing position, which is opposed to the front first cathode unit 72. The electrostatic chuck shifter 80 is also driven to shift the electrostatic chuck 73 to the contact position. The positive electrode power supply 86 and the negative electrode power supply 87 supply power to the positive electrodes 84 and the negative electrodes 85 to attract the film substrate 15 to the insulation plate 81.

The vent 78 is driven, and the sputter gas is supplied into the plasma generation void S. This adjusts the sputter chamber 71 to a predetermined pressure. When high frequency power is supplied to the target power supply 76, plasma including positive ions of the sputter gas and electrons is formed in the plasma generation void S. The positive ions in the plasma are attracted to the surface of the target 75 having a negative potential. Thus, the positive ions are sputtered on the surface of the target 75, and titanium particles reach one film formation surface (right surface 15a) of the film substrate 15 to form a Ti layer, which is a thin film containing titanium as the main component.

The transport motors 26 are further driven to locate the film substrate 15 at a position opposed to the first cathode unit 72 of the rear sputtering portion 70B. Subsequently, in the same manner as the front sputtering portion 70A, the rear sputtering portion 70B performs sputtering on the other film formation surface (left surface 15b). During this time, the film formation surface (right surface 15a), on which the Ti layer is formed by the front sputtering portion 70A, is in contact with and cooled by the electrostatic chuck 73.

### [Operation of Entire Substrate Processing Apparatus]

The operation of the substrate processing apparatus 10 will now be described focusing on the backward structural body 22 with reference to FIG. 5.

The controller 12 drives the first substrate lift 13 and the transport motors 26 to transport the film substrate 15, which is attached to the substrate holder 14 at the substrate attachment portion 11, into the forward structural body 21.

The controller 12 drives the heaters 31 of the forward structural body 21 and also controls the transport motors 26 of the forward structural body 21 to heat the film substrate 15, which is attached to the substrate holder 14, during the transportation. Thus, before transported to the backward structural body 22, the film substrate 15 is heated and degassed in advance during the transportation in the forward structural body 21.

If the forward structural body 21 transports only the substrate holder 14, and the film substrate 15 is attached to the substrate holder 14 at the entrance of the backward structural body 22, heating process is performed only by the heaters 40 of the first preliminary chamber 36. However, in the present embodiment, the film substrate 15 is attached to the substrate holder 14 and heated during the forward transportation, which is prior to transportation of the film substrate 15 into the first sputtering device 70. The heating time is longer than heating time in the first preliminary chamber 36. This ensures sufficient time for the degassing process.

Additionally, when the controller 12 drives the transport rollers 25 or the like to unload one film substrate 15 from the backward structural body 22, the controller 12 drives the second substrate lift 30 to transport another film substrate 15, which has arrived at a terminal position of the forward structural body 21, to the backward structural body 22. That is, the controller 12 performs the control so that the number of the film substrates 15 that exist in the backward structural body 22 is substantially constant.

The controller 12 drives the transport motors 26 to transport the film substrate 15 located in front of the entrance of the loading chamber 35 to the first preliminary chamber 36 through the loading chamber 35. Additionally, the controller 12 drives the heaters 40 of the first preliminary chamber 36 while adjusting the temperature to be the foregoing upper limit temperature or below. This performs the final degassing process prior to film formation.

The controller 12 drives the transport motors 26 to transport the film substrate 15, which has been heated in the first preliminary chamber 36 for a predetermined time, into the reverse sputtering device 50 and locate the film substrate 15 at the predetermined position of the front side with respect to the substrate transport direction. The controller 12 controls the reverse sputtering device 50 to perform reverse sputtering on the right surface 15a of the film substrate 15.

When reverse sputtering has been continuously performed on the right surface 15a for the predetermined time, the controller 12 drives the transport motors 26 to transport the film substrate 15 to the predetermined position of the rear side. Then, the controller 12 controls the reverse sputtering device 50 to perform reverse sputtering on the left surface 15b of the film substrate 15.

When the reverse sputtering step is finished, the controller 12 drives the transport motors 26 to transport the film substrate 15 into the first sputtering device 70 and locate the film substrate 15 at the opposing position, which is opposed to the front first cathode unit 72. The controller 12 controls the first sputtering device 70 to form a Ti layer on the right surface 15a, which is opposed to the first cathode unit 72.

When sputtering has been continuously performed on the right surface 15a for a predetermined time, the controller 12 drives the transport motors 26 of the backward structural body 22 to locate the film substrate 15 at the position opposed to the rear first cathode unit 72. The controller 12 controls the first sputtering device 70 to form a Ti layer on the left surface 15b, which is opposed to the first cathode unit 72.

When the film formation step of the Ti layer on the left surface 15b is finished, the controller 12 drives the transport motors 26 of the backward structural body 22 to transport the film substrate 15 into the second sputtering device 90 and locate the film substrate 15 at an opposing position opposed to the front second cathode unit 92. In the same manner as the film formation step of the Ti layer performed by the first sputtering device 70, the controller 12 forms Cu layers in the order of the right surface 15a and the left surface 15b.

When the Cu-layer film formation is finished, the controller 12 drives the transport motors 26 to transport the film substrate 15 into the second preliminary chamber 37. The controller 12 further drives the transport motors 26 to transport the film substrate 15 from the second preliminary chamber 37 to the substrate attachment portion 11 through the unloading chamber 38. The substrate attachment portion 11 detaches the film substrate 15 from the substrate holder 14.

As described above, the film substrates 15 are linearly transported through the forward structural body 21 and the backward structural body 22. In the backward structural body 22, reverse sputtering, Ti-layer film formation, Cu-layer film formation are performed on the film substrates 15 in parallel. Film formation is alternately performed on two surfaces of each film substrate 15 one surface at a time by the first sputtering device 70 and the second sputtering device 90 of the backward structural body 22. This eliminates the need for rotating the film substrate 15 to invert the film formation surface. Additionally, increases in temperature caused by the substrate processing are limited. Thus, increases in the temperature of the film substrate 15 are limited without extending the transport distance between the cathode units, lowering outputs of the sputtering devices, or the like. This shortens time from when the film substrate 15 is loaded on the backward structural body 22 until the film substrate 15 is unloaded from the backward structural body 22 thereby increasing the production efficiency of the substrate processing apparatus 10 when performing film formation on two surfaces one surface at a time.

The film substrate 15 is heated in the forward structural body 21 until the substrate holder 14 is transported to the entrance of the backward structural body 22. To remove moisture or the like from the film substrate 15 by heating at the upper limit temperature or below, the film substrate 15 needs to be heated for a predetermined time or longer. In this regard, when the film substrate 15 is heated in the forward structural body 21, the heating time in the first preliminary chamber 36 is shortened as compared to when only the first preliminary chamber 36 functions as a heating chamber.

When the electrostatic chucks of a sputtering device include bias electrodes, the reverse sputtering device 50 and the sputtering device may be integrated. However, when the reverse sputtering device 50 and the sputtering device are integrated, the film substrate 15 needs to be rotated in the device or transported in a direction opposite to the substrate transport direction. In this regard, the reverse sputtering device 50, the first sputtering device 70, and the second sputtering device 90 are arranged as separate substrate processing devices. This eliminates the need to rotate the film substrate 15 and transport the film substrate 15 in the direction opposite to the substrate transport direction.

The embodiment has the advantages described below.

(1) In the first sputtering device 70, the first cathode unit 72 located at the front side of the backward transport passage 32 forms a thin film on one film formation surface (right surface 15a) of the film substrate 15, which is opposed to the first cathode unit 72. Additionally, the first cathode unit 72 located at the rear side forms a thin film on the other film formation surface (left surface 15b) of the film substrate 15, which is opposed to the first cathode unit 72. In the same manner as the first sputtering device 70, the second sputtering device 90 forms a thin film on one surface at a time. This allows film formation to be performed on two film formation surfaces one surface at a time without rotating the film substrate 15. This increases the production efficiency in double-surface film formation.

(2) Four film formation portions, which include the two first cathode units 72 of the first sputtering device 70 and the two second cathode units 92 of the second sputtering device 90, are alternately arranged at one side and the other side of the backward transport passage 32. Thus, even when film formation is performed twice on each of two surfaces of the film substrate 15, the film formation is performed on one surface at a time without rotating the film substrate 15. This increases the production efficiency in double-surface film formation.

(3) In the reverse sputtering device 50, the bias electrode 62 located at the front side of the backward transport passage 32 attracts the positive ions to a film formation surface that is located at a side opposite to the bias electrode 62. Thus, reverse sputtering is performed on the film formation surface. Additionally, the bias electrode 62 located at the rear side of the backward transport passage 32 performs reverse sputtering on a film formation surface located at a side opposite to the bias electrode 62. This allows reverse sputtering to be performed on one surface at a time without rotating the film substrate 15. This increases the production efficiency in double-surface film formation.

(4) The film substrate 15 is heated by the heaters 31 of the forward structural body 21, which transports the film substrate 15 attached to the substrate holder 14 to the loading side of the backward structural body 22 from the unloading side of the backward structural body 22. The heaters 31 heat the film substrate 15 at the upper limit temperature, at which deformation of the film substrate 15 is prevented, or below. Thus, the film substrate 15 is degassed while preventing deformation or the like of the film substrate 15.

(5) The controller 12 loads a film substrate 15 onto the backward structural body 22 in accordance with unloading of another film substrate 15 from the backward structural body 22. Thus, film substrates 15 that have been preheated are sequentially transported at timings that allow for the process in the backward structural body 22. This increases the production efficiency in double-surface film formation.

The embodiment may be modified as follows.

The substrate holder may have a structure that differs from the embodiment.

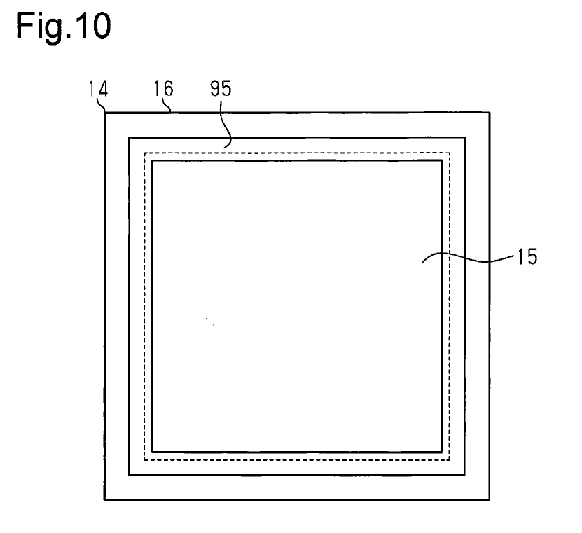

For example, as illustrated in FIG. 10, the substrate holder 14 may include the frame 16 and a substrate fastener 95, which is tetragonal frame-shaped and arranged along inner surfaces of the frame 16. The substrate fastener 95 fastens the entire edges of the film substrate 15. Thus, the film substrate 15 is firmly fastened.

The resin film substrate 15 serves as a substrate subject to film formation. Instead, the substrate subject to film formation may be formed from a material other than resin. The substrate subject to film formation may be a rigid substrate forming a print circuit board such as a paper phenol substrate, a glass epoxy substrate, a Teflon substrate (Teflon is a registered trademark), a ceramic substrate formed from alumina or the like, or a low-temperature co-fired ceramic (LTCC) substrate. Alternatively, a print circuit board formed by forming a metal wiring layer on the above substrates may be used. Also, the substrate subject to film formation is a substrate on which an electronic component is mounted. Instead, a substrate forming a thin film rechargeable battery cell or the like may be used.

In the embodiment, the targets 75 of the first sputtering device 70 contain titanium as the main component, and the targets 75 of the second sputtering device 90 contain copper as the main component. However, there is no limit to such configurations. The targets 75 of the first sputtering device 70 or the targets 75 of the second sputtering device 90 may contain, for example, chromium as the main component. Alternatively, at least two of titanium, copper, and chromium may be the main components.

In the embodiment, the heaters 31 arranged in the substrate transport direction form a heating portion of the forward structural body 21. The heating portion may be formed by a heater that extends in the longitudinal direction of the forward structural body 21.

When the film substrate 15 is formed from a material having a low hygroscopic property, the heaters 31 may be omitted from the forward structural body 21.

The first sputtering device 70 and the second sputtering device 90 may each have a configuration other than the above configuration. The electrostatic chucks 73 of the first sputtering device 70 and the electrostatic chucks 93 of the second sputtering device 90 may be configured, for example, to include bias electrodes. The first sputtering device 70 and the second sputtering device 90 may each have a configuration that does not include the magnet circuits 77.

The substrate holder 14 is configured to include the frame 16 and the substrate fasteners 17. However, the configuration only needs to be such that film formation can be performed on two film formation surfaces. In one example, the substrate holder may be configured to hold the edges of the film substrate 15 between two frames. In another example, the substrate holder may be a tray having an opening that exposes the film formation surfaces.

In the embodiment, the substrate processing apparatus 10 includes the reverse sputtering device 50. When performing a pre-process for cleaning the film formation surfaces of the film substrate 15, the reverse sputtering device 50 may be omitted.

In the embodiment, the two sputtering devices are coupled. However, the number of sputtering devices may be changed in accordance with the structure of thin films that are to be formed. For example, one sputtering device may be used. Alternatively, three or more sputtering devices may be coupled.

The substrate processing apparatus 10 may process a substrate other than a thin substrate such as the film substrate 15. When a substrate that prefers film formation at a relatively low temperature is subject to the process, the same advantages as the present embodiment are obtained.

1. A substrate processing apparatus comprising:
a sputter chamber;
two targets located in the sputter chamber to form thin films on two film formation surfaces of a substrate through sputtering; and
a transport mechanism that transports the substrate along a transport passage located in the sputter chamber, wherein
one of the two targets is located at one side of the transport passage opposed to one of the two film formation surfaces of the substrate at a front side with respect to a direction in which the substrate is transported, and
another one of the two targets is located at another side of the transport passage opposed to another one of the two film formation surfaces of the substrate at a rear side with respect to the direction in which the substrate is transported.

2. The substrate processing apparatus according to claim 1, wherein
the sputter chamber is one of a first sputter chamber and a second sputter chamber that are arranged next to each other to be at the front side and the rear side with respect to the transport direction, and
the two targets located in the first sputter chamber and the two targets located in the second sputter chamber are located at different positions in the transport direction alternately at one side and the other side of the transport passage.

3. The substrate processing apparatus according to claim 1, further comprising:
a reverse sputter chamber that cleans the two film formation surfaces of the substrate when the substrate is transported to the reverse sputter chamber prior to transportation to the sputter chamber; and
two bias electrodes located in the reverse sputter chamber, wherein bias voltage is applied to the two bias electrodes,
wherein the two bias electrodes are separately located at the front side and the rear side with respect to the transport direction and at one side and the other side of the transport passage.

4. The substrate processing apparatus according to claim 1, further comprising:
a backward structural body including the sputter chamber;
a substrate attachment portion located at an unloading port side of the backward structural body and configured to attach the substrate to a substrate holder; and
a forward structural body that transports the substrate, which is attached to the substrate holder, from an unloading port side of the backward structural body to a loading port side of the backward structural body, wherein the forward structural body includes a heating portion that heats the substrate at a preset upper limit temperature or below.

5. The substrate processing apparatus according to claim 4, wherein
the transport mechanism includes a controller that controls transportation of the substrate to the forward structural body and transportation of the substrate to the backward structural body from the forward structural body, and
in accordance with unloading of the substrate from the backward structural body, the controller loads a substrate, on which a film has not yet been formed, onto the backward structural body from the forward structural body.
